(19) United States
(12) Patent Application Publication
(10) Pub. No.: US 2026/0068361 A1
(43) Pub. Date: Mar. 5, 2026

(54) NANOWIRE DEVICE WITH MASK LAYER

(71) Applicants: CRAYONANO AS, Trondheim (NO); NORWEGIAN UNIVERSITY OF SCIENCE AND TECHNOLOGY (NTNU), Trondheim (NO)

(72) Inventor: Helge WEMAN, Ecublens (CH)

(21) Appl. No.: 19/106,343

(22) PCT Filed: Aug. 25, 2023
(86) PCT No.: PCT/EP2023/073384

§ 371 Date: Feb. 25, 2025

(30) Foreign Application Priority Data
Aug. 25, 2022 (GB) 2212397.0

(51) Int. Cl. H10H 20/813; H10H 20/01; H10H 20/812; H10H 20/825

(52) U.S. Cl. CPC H10H 20/8132; H10H 20/013; H10H 20/812; H10H 20/825

(57) ABSTRACT

A composition of matter comprising a doped substrate a mask layer having a thickness of 2 nm or less on top of said substrate wherein a plurality of openings are present through said mask layer; and wherein a plurality of nanowires or nanopyramids are grown from said substrate in said openings, said nanowires or nanopyramids comprising at least one semiconducting group III-V compound.

This invention concerns compositions comprising nanowires or nanopyramids grown on a doped substrate through a mask layer. The compositions of matter that are formed can be used in an electronic device such as an LED, solar cell, transistor, laser or photodetector. The invention also concerns compositions/devices comprising nanowires or nanopyramids on a metal substrate through a mask layer.

### BACKGROUND

Over recent years, the interest in semiconductor nanowires has intensified as nanotechnology becomes an important engineering discipline. Nanowires, which are also referred to as nanowhiskers, nanorods, nanopillars, nanocolumns, etc. by some authors, have found important applications in a variety of electrical devices such as sensors, solar cells, transistors and LED's.

Conventionally, semiconductor nanowires have been grown on a substrate identical to the nanowire itself (homoepitaxial growth). Thus, GaAs nanowires are grown on GaAs substrates, GaN nanowires are grown on GaN substrates, and so on. This, of course, ensures that there is a lattice match between the crystal structure of the substrate and the crystal structure of the growing nanowire. In case of heteroepitaxial growth, GaN nanowires are grown on sapphire or silicon substrates and so on. Both substrate and nanowire can have identical crystal structures.

In order to position the nanowires, it is known to use a mask with a hole array pattern where nanowires are allowed to grow only/mainly in the hole-patterned area. The mask can also promote NW growth in a direction perpendicular to the substrate. Typically, a silica layer is applied to a substrate and etched to create holes in a desired pattern. Nanowires then grow only/mainly at the location of the holes.

The growth of nanowires (NWs) on graphene is known where the graphene acts as an electrode. In WO2012/080252, there is a discussion of the growth of semiconducting nanowires on graphene substrates. WO2013/104723 concerns improvements on the WO2012/080252 disclosure in which a graphene top contact is employed on NWs grown on graphene. In these cases however nanowire growth occurs on the graphene layer and not on the substrate underneath.

Graphene has been suggested as a possible mask layer and electrode (WO2021/009325). However, it can be difficult to achieve good electrical contact with graphene.

The present inventors propose to use a thin mask layer on a doped substrate. Nanowires/nanopyramids are grown through openings (e.g. patterned holes, or defects) in said mask layer. The doped substrate is an active substrate which can participate in the functioning of the device. The mask layer can act as a tunnelling barrier to improve vertical conduction in the device, and thus improve efficiency. Similar benefits can be seen when a metal (electrically conductive) substrate is used.

### SUMMARY OF INVENTION

Thus viewed from one aspect there is provided a composition of matter comprising:
a doped substrate;
a mask layer having a thickness of 2 nm or less on top of said substrate,
wherein a plurality of openings are present through said mask layer; and wherein
a plurality of nanowires or nanopyramids are grown from said substrate in said holes, said nanowires or nanopyramids comprising at least one semiconducting group III-V compound.

In a further aspect, there is provided a composition of matter comprising:
doped substrate;
a mask layer having a thickness of 2 nm or less on top of said substrate
wherein a plurality of openings are present through said mask layer; and
a corrugated continuous III-V film present on top of said mask layer and extending from said holes, e.g. formed from a plurality of coalesced nanowires or nanopyramids grown in said holes, said nanowires or nanopyramids comprising at least one semiconducting group III-V compound.

In a further aspect, there is provided a device, such as an opto-electronic device, comprising a composition as defined herein, e.g. a solar cell, photodetector, transistor, laser, or LED, preferably an LED, more preferably a UV LED, more preferably a UV-C LED.

In a further aspect, there is provided a process for preparing a composition as defined herein comprising:
(I) providing a mask layer having a thickness of 2 nm or less carried on a doped substrate;
(II) growing a plurality of nanowires or nanopyramids from said substrate in a plurality of openings in said mask layer, said nanowires or nanopyramids comprising at least one semiconducting group III-V compound.

In a further aspect, there is provided a process for preparing a composition as defined herein comprising:
(I) providing a mask layer having a thickness of 2 nm or less carried on a doped substrate;
(II) growing a plurality of nanowires or nanopyramids from said substrate in a plurality of openings in said mask layer, said nanowires or nanopyramids comprising at least one semiconducting group III-V compound, to the point that the nanowires or nanopyramids are coalesced.

In a further aspect, there is provided a composition of matter comprising:
a metal substrate;
a mask layer having a thickness of 2 nm or less on top of said substrate,
wherein a plurality of openings are present through said mask layer; and wherein
a plurality of nanowires or nanopyramids are on said substrate in said openings, said nanowires or nanopyramids comprising at least one semiconducting group III-V compound.

In a further aspect, there is provided a composition of matter comprising:
a metal substrate;
a mask layer having a thickness of 2 nm or less on top of said substrate
wherein a plurality of openings are present through said mask layer; and a corrugated continuous III-V film present on top of said mask layer and extending from said openings, e.g. formed from a plurality of coalesced nanowires or nanopyramids grown in said openings, said nanowires or nanopyramids comprising at least one semiconducting group III-V compound.

In a further aspect, there is provided a process for the preparation of a device, such as an opto-electronic device, comprising steps of:
(I) removing the nanowires or nanopyramids from the substrate in the composition as defined herein; and
(II) transferring the removed nanowires or nanopyramids to a different substrate, wherein said second substrate is doped/conductive or undoped/insulating

In a further aspect, there is provided a process for the preparation of a device, such as an opto-electronic device, comprising steps of:
(I) removing the continuous III-V film from the substrate in the composition as defined herein; and
(II) transferring the removed III-V film to a different substrate, wherein said second substrate is doped/conductive or undoped/insulating.

The features of the aspects and/or embodiments indicated herein are usable individually and in combination in all aspects and embodiments of the invention where technically viable, unless otherwise indicated.

### DEFINITIONS

By a group III-V compound semiconductor is meant one comprising at least one element from group III and at least one element from group V. There may be more than one element present from each group, e.g. InGaAs, AlGaN (i.e. a ternary compound), AllnGaN (i.e. a quaternary compound) and so on. The term semiconducting nanowire or nanopyramid is meant nanowire or nanopyramid made of semiconducting materials from group III-V elements.

The term nanowire is used herein to describe a solid, wire-like structure of nanometer dimensions. Nanowires preferably have an even diameter throughout the majority of the nanowire, e.g. at least 75% of its length. The term nanowire is intended to cover the use of nanorods, nanopillars, nanocolumns or nanowhiskers some of which may have tapered end structures. The nanowires can be said to be in essentially in one-dimensional form with nanometer dimensions in their width or diameter and their length typically in the range of a few 100 nm to a few um. Ideally the nanowire diameter (width) is not greater than 500 nm. Ideally the nanowire diameter (width) is between 50 and 500 nm, however, the diameter can exceed few micrometers (called microwires).

Ideally, the diameter at the base of the nanowire and at the top of the nanowire should remain about the same (e.g. within 20% of each other).

The term nanopyramid refers to a solid pyramidal type structure. The term pyramidal is used herein to define a structure with a base whose sides taper to a single point generally above the centre of the base. It will be appreciated that the single vertex point may appear chamfered, e.g. such that the pyramid has a flat top Typically, the chamfered portion is equivalent to less than 50%, e.g. less than 40%, e.g. less than 30%, e.g. less than 20%, e.g. less than 10%, e.g. less than 5% of the total length of the nanopyramid edge. The nanopyramids may have multiple faces, such as 3 to 8 faces, or 4 to 7 faces. Thus, the base of the nanopyramids might be a square, pentagonal, hexagonal, heptagonal, octagonal and so on. The pyramid is formed as the faces taper from the base to a central point (forming therefore triangular faces). The triangular faces are normally terminated with (1-101) or (1-102) planes. The triangular side surfaces with (1-101) facets could either converge to a single point at the tip or could form a new facets ((1-102) planes) before converging at the tip. In some cases, the nanopyramids are truncated with its top terminated with {0001} planes. The base itself may comprise a portion of even cross-section before tapering to form a pyramidal structure begins. The thickness of the base may therefore be up to 500 nm, e.g. up to 200 nm, such as 50 nm.

The base of the nanopyramids can be 50 and 500 nm in diameter (width) across its widest point. In another embodiment, the base of the nanopyramids can be 200 nm to 1 (one) micrometer in diameter (width) across its widest point. The height of the nanopyramids may be 200 nm to a few micrometers, such as 400 nm to 1 micrometer in length.

It will be appreciated that the substrate comprises a plurality of nanowires or nanopyramids. This may be called an array of nanowires or nanopyramids.

Graphene layers are films composed of single or multiple layers of graphene or its derivatives. The term graphene refers to a planar sheet of sp²-bonded carbon atoms in a honeycomb crystal structure. Whilst it is preferred to use graphene it is also possible to use derivatives of graphene such as those with surface modification. For example, the hydrogen atoms can be attached to the graphene surface to form graphane. Graphene with oxygen atoms attached to the surface along with carbon and hydrogen atoms is called as graphene oxide. The surface modification can be also possible by chemical doping or oxygen/hydrogen or nitrogen plasma treatment.

The term epitaxy comes from the Greek roots epi, meaning “above”, and taxis, meaning “in ordered manner”. The atomic arrangement of the nanowire or nanopyramid is based on the crystallographic structure of the substrate. Typically, there is no epitaxial relationship between the nanowires/nanopyramids with the mask layer. It is a term well used in this art. Epitaxial growth means herein the growth on the substrate of a nanowire or nanopyramid that mimics the orientation of the substrate.

Selective area growth (SAG) is the most promising method for growing positioned nanowires or nanopyramids. This method is different from the self-assembled metal catalyst assisted vapour-liquid-solid (VLS) method, in which metal catalyst act as nucleation sites at random locations for the growth of nanowires or nanopyramids. Another self-assembled method to grow nanowires or nanopyramids is catalyst-free method, where nanowires or nanopyramids are nucleated in random positions. These methods yield huge fluctuations in the length and diameter of the nanowires and the height and width of nanopyramids. Positioned nanowires or nanopyramids can also be grown by the catalyst-assisted method.

The SAG method or the catalyst-assisted positioned growth method typically requires a mask with nano-hole patterns on the substrate. The nanowires or nanopyramids nucleate mainly in the holes of the patterned mask on the substrate. This yields uniform size and pre-defined position of the nanowires or nanopyramids. The nanowires/nanopyramids may also nucleate on the substrate in any defects in the mask layer which expose the underlying substrate.

Molecular beam epitaxy (MBE) is a method of forming depositions on crystalline substrates. The MBE process is performed by heating a crystalline substrate in a vacuum so as to energize the substrate's lattice structure. Then, an atomic or molecular mass beam(s) is directed onto the substrate's surface. The term element used above is intended to cover application of atoms, molecules or ions of that element. When the directed atoms or molecules arrive at the substrate's surface, the directed atoms or molecules encounter the substrate's energized lattice structure or a catalyst droplet as described in detail below. Over time, the oncoming atoms form a nanowire.

Metalorganic vapour phase epitaxy (MOVPE) also called as metalorganic chemical vapour deposition (MOCVD) is an alternative method to MBE for forming depositions on crystalline substrates. In case of MOVPE, the deposition material is supplied in the form of metalorganic precursors, which on reaching the high temperature substrate decomposes leaving atoms on the substrate surface. In addition, this method requires a carrier gas (typically H₂ and/or N₂) to transport deposition materials (atoms/molecules) across the substrate surface. These atoms reacting with other atoms form an epitaxial layer on the substrate surface. Choosing the deposition parameters carefully results in the formation of a nanowire.

The term carried directly implies that the layers in question are adjacent.

### Mask Layer

The mask layer can serve several purposes. The openings in the mask allow the NW/NP material to be epitaxial with the substrate (NW=nanowire, NP=nanopyramid). The mask layer surprisingly also acts a tunnel junction for conduction from the substrate to the NWs/NPs (or from the NWs/NPs to the substrate), for the portions of the NWs/NPs which extend laterally over the mask layer (i.e. outside of the openings). The deliberate patterning of openings in the mask layer can enable the positioning (i.e. SAG) of the nanowires/nanopyramids.

The mask layer may comprise or consist of a two-dimensional (2D) material. By two-dimension material is meant herein a material with a layered structure, e.g. one with a structure formed of sheets stacked on top of each other, preferably wherein the sheets are held together by van der Waals forces. The two-dimensional material may be graphene, hexagonal-BN (h-BN), MoS₂, WS₂, MoSe₂, NbSe₂, TaSe₂, Bi₂Te₃, Bi₂Se₃ or NiTe₂. Whilst graphene is preferred, other ‘graphene-like’ materials with two-dimensional structures are therefore suitable herein, e.g. hexagonal-BN, MoS₂, WS₂, MoSe₂, NbSe₂, TaSe₂, Bi₂Te₃, Bi₂Se₃ or NiTe₂ layer.

The mask layer may therefore be a graphene, hexagonal-BN, MoS₂, WS₂, MoSe₂, NbSe₂, TaSe₂, Bi₂Te₃, Bi₂Se₃ or NiTe₂ mask layer. Preferably, the mask layer is a graphene mask layer or a h-BN mask layer, most preferably a graphene mask layer.

As used herein, the term graphene refers to a planar sheet of sp²-bonded carbon atoms that are densely packed in a honeycomb (hexagonal) crystal lattice. The term ‘graphene’ also means structures having a small number of graphene sheets. The interplanar spacing in graphene is 0.335 nm.

The mask layer should ideally contain 10 sheets or less of two-dimensional material (i.e. graphene or graphene-like material), preferably 5 sheets or less, preferably 4 sheets or less, preferably 3 sheets or less, preferably 2 sheets or less of two-dimensional material. Preferably the mask layer should contain 1-5 sheets, preferably 1-4 sheets, preferably 1-3 sheets, preferably 1-2 sheets of two-dimensional material, most preferably 1 sheet of two-dimensional material (i.e. a monolayer of graphene or graphene-like material). Especially preferably, it is a one-atom-thick planar sheet of graphene.

In terms of metric thicknesses, it is preferred if the mask layer in general is 2 nm in thickness or less. The mask layer preferred comprises only a few sheets of two-dimensional material (i.e. graphene or graphene-like material) and is ideally less than 1.5 nm in thickness. Even more preferably, the mask layer may be 1 nm or less in thickness, more preferably 0.9 nm or less in thickness, more preferably 0.8 nm or less in thickness, more preferably 0.7 nm or less in thickness, more preferably 0.6 nm or less in thickness, more preferably 0.5 nm or less in thickness. Preferred thickness ranges include 0.3-2 nm, preferably 0.3-1.5 nm, e.g. 0.3-1 nm, 0.3-0.9 nm, 0.3-0.8 nm, 0.3-0.7 nm e.g. 0.3-0.5 nm.

The mask layer can act as (or is) a tunnel barrier, e.g. for carrier tunnel injection from the doped substrate to the group III-V nanowires or nanopyramids. The carrier tunnel injection typically occurs where the nanowires/nanopyramids are extended laterally over the mask layer. Having a thin mask layer is important for the electronic properties. The thinner the mask layer, the better the tunnelling between the substrate and the nanowire/nanopyramid. Particularly efficient tunnelling through the mask is obtained when the mask layer is one or two atomic layers thick, preferably when the mask layer is a one-atom thick sheet of graphene. Mask layers that are much thicker than the above thicknesses will typically not exhibit the beneficial tunnelling required, and hence will have poor tunnelling efficiency.

The portion of the nanowire or nanopyramid that extends over the mask layer is in contact with the mask layer. Typically, a conductive pathway is present from the substrate, through the mask layer and into the nanowires or nanopyramids. Said conductive pathway is through the region of the nanowires/nanopyramids that extends over the mask layer. The mask layer may therefore act as a tunnel barrier between the substrate and the portions of the NWs/NPs which extends over the mask layer (i.e. outside the openings).

The area of the mask layer in general is not limited. This might be as much as 0.5 mm² or more, e.g. up to 5 mm² or more such as up to 10 cm2. The area of the mask layer is thus only limited by practicalities. Graphene wafers, for example, may be 1.0 to 100 square inches, such as 2 square inches or even 50 square inches in size.

In a highly preferred embodiment, the mask layer is single layer or multi-layer graphene (preferably single layer) grown on metal catalysts by using a chemical vapour deposition (CVD) method. Metal catalysts can be metallic films or foils made of e.g. Cu, Ni, or Pt. Transfer of the graphene layer grown on these metal catalysts to another substrate can be affected by techniques discussed in detail below. The graphene layer can also be directly grown on the doped substrate (e.g. doped Si, Ge or III-V substrate). In that case, transfer process is not required. The graphene layer can also be grown on SiC substrate using thermal sublimation process and may be transferred onto a target substrate if needed.

The graphene layer is preferably used without any surface modification.

The mask layer (e.g. graphene) may be doped to improve its electrical conductivity. This may be beneficial if the mask layer acts as an electrode (e.g. as a gate for a vertical transistor). The mask layer might be washed with iso-propanol, acetone, or n-methyl-2-pyrrolidone to eliminate surface impurities. The cleaned graphene surface can be further modified by doping. A solution of FeCl₃, AuCl₃ or GaCl₃ could be used in a doping step.

The graphene layer is well known for its superior optical, electrical, thermal and mechanical properties. They are very thin but very strong, light, flexible, and impermeable. Most importantly in the present invention they are thin tunnelling barriers and hole masks for the SAG of the nanowires/nanopyramids.

Where the nanowires or nanopyramids extend laterally over the mask outside of the openings, there is good electrical contact between the nanowire/nanopyramid and the substrate below vertically through the tunnel barrier layer. The nanowires or nanopyramids typically nucleate in the openings (whether patterned holes or defects) of the mask on the substrate, and then grow laterally, i.e. radially, over the top surface of the mask layer (i.e. they ‘mushroom’ out of the openings). Typically, the nanowire or nanopyramid core extends laterally (i.e. radially) over the mask layer outside of the mask openings. The portion that extends over the mask layer is in direct contact and/or electrical contact with the mask layer. ‘Lateral’ or ‘laterally’ herein means in the same plane as the substrate and/or mask layer.

It is preferred herein if the mask layer is not an electrode, or does not act as an electrode. Preferably, there is no electrical contact on the graphene layer. For certain applications, e.g. transistors, it may be beneficial for the mask layer to act as an electrode. In a particular embodiment, therefore, the mask layer acts (or is) an electrode. The composition may therefore have an electrical contact in (direct, i.e. physical as well as electrical) contact with the mask layer. This can reduce the tunnel barrier and thereby enhance vertical tunnelling current.

The mask layer is typically positioned directly on the substrate (or, if a silicon substrate is used, on an intermediate native silicon oxide film which typically covers the silicon substrate). The mask layer is planar.

The openings in the mask layer may be any kind of opening. They may be patterned holes (i.e. ‘deliberate’ positioned holes) or pre-existing defects in the mask layer. They may also be defects formed during the growth of the nanowires/nanopyramids. The openings may be positioned holes or defect openings in the mask layer. The openings may be of any size, and can range from an atomic vacancy defect in the mask layer to a patterned hole of up to, for example, 500 nm in diameter. The openings may be of any shape, e.g. they may be circular holes or elongated openings like a grain boundary or crack. By opening herein is meant an opening in the mask layer which exposes the surface of the substrate. The openings in the mask layer are openings which enable nucleation, typically epitaxial nucleation, of the nanowires/nanopyramids from the substrate.

One nanowire or nanopyramid preferably grows per opening.

### Patterning

The nanowires or nanopyramids grow initially, or nucleate, from the substrate. This occurs in/from the openings present in the mask layer. These openings can be in the form of holes (deliberately) patterned in the mask layer.

Making of these holes is a well-known process and can be carried out using e-beam lithography and etching or any other known techniques. The hole patterns in the mask can be easily fabricated using conventional lithography techniques such as photo/e-beam lithography, nanoimprinting, and so on. Focussed ion beam technology may also be used in order to create a regular array of nucleation sites on the substrate surface for the nanowire or nanopyramid growth. The holes created in the masking and seed layers can be arranged in any pattern which is desired.

The diameter of the holes is preferably up to 500 nm, such as up to 100 nm, ideally up to 20 to 200 nm. The diameter of the hole sets a maximum diameter for the size of the nanowires or nanopyramids during initial growth. However, nanowire or nanopyramid diameter larger than the hole size can be achieved by changing the growth parameters or by adopting a core-shell nanowire or nanopyramid geometry. Preferably, the nanowires or nanopyramids extend laterally (i.e. radially) over the mask outside of the holes.

The number of holes is a function of the area of the and desired nanowire or nanopyramid density.

The shape of the holes is not limited. Whilst these may be circular, holes may also be in other shapes, such as triangular, rectangles, oval etc. A ‘hole’ is herein typically defined as having its smallest lateral dimension within 75% of its longest lateral dimension. The mask layer may be in electrical contact with the base of the nanowires or nanopyramids, which is useful in the case of the mask layer acting as an electrode.

As the nanowires or nanopyramids begin growing within a hole, this tends to ensure that the initial growth of the nanowires or nanopyramids is epitaxial and substantially perpendicular to the substrate. This is a further preferred feature of the invention.

### Defect Openings

The openings in the mask layer may also be defects in the mask layer. The defects may be formed during the mask growth/preparation or during the nanowire/nanopyramid growth. The openings may be any type of defect, e.g. point, grain boundary, areal or crack defects in the mask layer (see Qin et al., Journal of Applied Mechanics 2020, vol 87, 030802-1 to 030802-11). The defect openings are typically randomly positioned and are typically smaller than the positioned/patterned holes. A defect opening in the present case may be of any size and of any shape. The defect openings expose the surface of the substrate, and enable the nucleation, typically epitaxial nucleation, of the nanowires/nanopyramids from the substrate.

As mentioned above, the defects may be pre-existing defects in the mask layer. They may also be defects formed during the growth of the nanowires/nanopyramids e.g. through annealing or ex- or in-situ plasma.

A point defect may be a vacancy, a dislocation, or S-W defect (Stone-Wales defect). A vacancy is the absence of one or more atoms in the mask layer crystal structure. A single vacancy is the absence of a single atom, whilst a double vacancy is the absence of a pair of atoms. A dislocation in graphene is typically a pentagon-heptagon (5|7) pair. A S-W defect is a topological defect formed without addition of elimination of atoms. In graphene, a S-W defect converts four adjacent neighbouring hexagons into two pentagons and two heptagons (5|7|7|5). A heptagon can act as an opening through which the nanowires/nanopyramids can nucleate.

A grain boundary defect is an interface between two adjacent grains in the mask layer and is typically an array of dislocations arranged in a linear way.

By areal defect is herein meant a hole, typically formed by coalescence of a number of vacancies.

A crack defect is a crack in the mask layer. It is typically elongate, therefore.

### Substrate

The nanowires and nanopyramids typically grow initially from the substrate and hence it is preferred that the substrate is a crystalline substrate.

The substrate may have a crystal orientation of [111], [110], [100], or [0001] perpendicular to the surface. [100] and [111] are preferred, e.g. for cubic semiconductors like Si and GaAs. Commercially, [100] is preferred, but for NW/NP growth [111] is preferred. [0001] is also preferred, typically for SiC or III-N substrates. The substrate may therefore be [100] silicon or [111] silicon.

The substrate may be selected from silicon, Ge, SiC, Ga₂O₃ or group III-V substrates. The III-V materials described for the nanowires/nanopyramids are also suitable for the III-V substrates, and thus the definition of III-V materials for the nanowires/nanopyramids also apply for III-V substrates. Silicon is preferred as the substrate. Silicon is a cheap and versatile substrate that can easily be manipulated. It also offers good protection for the mask, and prevents oxidation (e.g. graphene oxidation if graphene is used). In particular, it is much more readily available than III-V semiconductor substrates, for example. The combination of a silicon substrate and graphene mask layer is advantageous as there can be excellent SAG for group III-V materials, in particular for Ga-V materials, as GaAs, GaN, GaSb and GaP. The silicon substrate is also nonpolar, which is beneficial to inhibit nucleation on the graphene mask during the SAG of the nanowires/nanopyramids. The substrate in the present invention is doped, i.e. n-doped or p-doped, typically p-doped. Preferably, it is highly doped (and thus labelled as ‘n++’ or ‘p++’). The doped substrate typically acts as an injector of current. The doped substrate can be an injector of electrons (if n-doped such as an ‘n++’ Si substrate) or injector of holes (if p-doped such as a ‘p++’ Si substrate). The high degree of doping is beneficial because this will lower the barrier height and facilitate (increase) the vertical tunnelling current between the substrate and the nanowires/nanopyramids. Moreover, substrates such as silicon can accommodate high doping levels, thus increasing current injection and efficiency of the device. One of the advantages of this invention is that when highly doped substrates are used (e.g. p++ Si), the hole injection can be much larger (as long as the tunnelling is made efficient through the mask layer) than expected due to the much higher doping density of the substrate compared to the doping density in the in the NW/NP cores. p++-silicon substrates can be doped to a much higher level than p-GaN NW/NPs, for example.

Doping of the substrate typically involves the introduction of impurity ions. The doping level can be controlled from ˜10¹⁵/cm³ to 10²²/cm³, e.g. 10¹⁸/cm³ to 10²¹/cm³ (these numbers refer to the number of doping/impurity ions per cm³). In a particular embodiment, the substrate is highly doped, e.g. has a doping level of at least 10¹⁵/cm³, preferably of at least 10¹⁶/cm³, preferably of at least 10¹⁷/cm³, preferably of at least 10¹⁸/cm³, preferably or of at least 10¹⁹/cm³. The substrate can be p-type doped or n-type doped. For applications such as UVC LED, the substrate is preferably p-type doped, but for other applications such as UVA/visible LED or photodetector devices, the substrate is preferably n-type doped.

Suitable acceptors for the substrate can be boron, aluminium, gallium, indium, when the substrate is p-type doped. The substrate may therefore be doped with at least one of boron, aluminium, gallium, or indium, preferably boron. For n-type substrates, suitable donors can be phosphorus, arsenic or antimony, preferably phosphorus. The substrate may therefore be doped with at least one of phosphorus, arsenic, or antimony. Dopants can be introduced during the growth process or by ion implantation after formation of the substrate.

In the case of a silicon substrate, there is typically a native SiO₂ layer on the silicon substrate. In the present invention, therefore, the term ‘silicon substrate’ does not exclude the presence of a very thin layer of SiO₂ on top of the substrate (i.e. at the interface with the graphene mask in the compositions/devices of the invention). In a particular embodiment, therefore, the silicon substrate comprises this native SiO₂ layer. The thickness of the top SiO₂ native layer is typically less than 20 nm, preferably less than 10 nm, preferably less than 5 nm, preferably less than 3 nm, preferably less than 2 nm, preferably less than 1.9 nm, preferably less than 1 nm, e.g. 1-5 nm, 1-2 nm or 2-3 nm. Since the SiO₂ layer is insulating a vertical current from the Si substrate can only take place by tunnelling, and the vertical tunnel current increase with decreased thickness of the native SiO₂ layer. The inventors have surprisingly found, therefore, that this insulating layer together with the mask layer can cause a conduction pathway. Furthermore, the inventors have surprisingly found that the oxide at the nanowire/silicon interface is much thinner (i.e. 1.0-1.5 mm) when nanowires (e.g. GaN nanowires) are grown with a graphene mask layer on a Si substrate (structures depicted in FIGS. 6a and 6b) compared to nanowires grown on a Si substrate without the graphene mask layer (i.e. 2.0-2.5 mm) (structures depicted in FIGS. 6c and 6d). Additionally, the conduction pathway between the n-doped nanowires and the n++ doped Si substrate is more efficient in the presence of a graphene mask layer compared to when the graphene mask is absent (FIG. 6e).

The substrate may act as a current injector. It is much easier to make electrical contact on the substrate than on graphene, for example. One can simply etch away some of the substrate and attach a metal as an electrical contact. It can be difficult to make electrical contact on graphene or other graphene-like materials. In a particular embodiment, the substrate is provided with an electrical contact (typically metallic), preferably a contact on the top side of the substrate (i.e. same side as the NWs/NPs). A portion of the top surface of the substrate can be etched away to connect an electrical contact, for example. The electrical contact enables vertical hole tunnel injection, or vertical electron tunnel injection. The substrate can therefore be/act as an electrode.

In a further embodiment, the nanowires or nanopyramids may be grown on a substrate, and then removed (e.g. delaminated) from the substrate and transferred to a different substrate. Removal may proceed via etching, peeling, spalling or electrochemical removal/delamination. The mask layer may be removed from the substrate in combination with the nanowires or nanopyramids, or the nanowires or nanopyramids may be removed from both the substrate and the mask layer. The nanowires or nanopyramids which have been removed from the original substrate may be transferred to a new substrate (optionally with the removed mask layer). The new substrate may comprise any features of a substrate mentioned herein. Alternatively, the new substrate may comprise a doped or conductive substrate like a metal (such as Co, Ti, Mo, stainless steel) which can act as an electrical contact. The new substrate may be rigid or as a thin film to allow for flexible devices. The electrical contact could enable vertical charge carrier tunnel injection to/from the doped/conductive substrate. A doped/conductive substrate can therefore be/act as an electrode.

With a metal substrate, for example, the same benefits of high electrical conduction from the substrate in terms of tunnelling through the mask layer apply.

The present invention therefore provides a composition of matter comprising
a metal substrate;
a mask layer having a thickness of 2 nm or less on top of said substrate,
wherein a plurality of openings are present through said mask layer; and wherein
a plurality of nanowires or nanopyramids are on said substrate in said openings, said nanowires or nanopyramids comprising at least one semiconducting group III-V compound.

The metal substrate is an electrically conductive metal in this instance, and is different from a semiconductor. The nanowires or nanopyramids are on said substrate, and are typically in direct and electrical contact with the substrate. The same considerations regarding their positioning on the metal substrate (e.g. perpendicular to the substrate) are the same as for the doped substrate.

In such an embodiment, the same characteristics for the mask layer, the nanowires/nanopyramids, the devices etc. apply as for the embodiment with the doped substrate, but for brevity are not repeated here.

The same considerations apply to any coalesced structures, i.e. non-planar films formed from the coalescence of the nanostructures or III-V continuous.

### Nanowires/Nanopyramids

Any discussion of nanowires (NWs) herein equally applies to nanopyramids (NPs), where technically viable. Discussion of nanowires/nanopyramids can refer to the nanowire/nanopyramid cores, or the cores in combination with additional layers positioned thereon.

In order to prepare nanowires or nanopyramids of commercial importance, it is preferred that these grow epitaxially on the substrate. It is also ideal if growth occurs perpendicular to the substrate and ideally therefore in the [111] (for cubic crystal structure) or [0001] (for hexagonal crystal structure) direction. The wording ‘grown from said substrate in said openings’ means that the NWs/NPs are located over the openings, and there is part of the nanowire/nanopyramid that extends (downwards) in the opening to the substrate, and preferably the NW/NP forms an epitaxial relationship with the substrate. Alternatively put, the NWs/NPs are present in the openings of the mask layer. Alternatively put, the nanowires/nanopyramids are nucleated from the openings in the mask layer, or extend therefrom.

In a growing nanopyramid, the triangular faces are normally terminated with (1-101) or (1-102) planes. The triangular side surfaces with (1-101) facets could either converge to a single point at the tip or could form new facets (1-102) planes before converging at the tip. In some cases, the nanopyramids are truncated with its top terminated with {0001} planes.

Preferably, the nanowires and/or nanopyramids have pyramidal tips.

Whilst it is ideal that there is no lattice mismatch between a growing nanowire or nanopyramid and the substrate layer, nanowires or nanopyramids can accommodate much more lattice mismatch than thin films for example.

Growth of nanowires/nanopyramids can be controlled through flux ratios. Nanopyramids are encouraged, for example if high group V flux is employed.

The nanowires that are grown can be said to be in essentially in one-dimensional form with nanometer dimensions in their width or diameter and their length typically in the range of a few 100 nm to a few um. Ideally the nanowire diameter is not greater than 500 nm. Ideally the nanowire diameter is between 50 and 500 nm; however, the diameter can exceed few micrometers (called microwires).

The nanowire grown in the present invention may therefore be from 250 nm to several micrometers in length, e.g. up to 5 micrometers. Preferably the nanowires are at least 1 micrometer in length. Where a plurality of nanowires are grown, it is preferred if they all meet these dimension requirements. Ideally, at least 90% of the nanowires grown on a substrate will be at least 1 micrometer in length. Preferably substantially all the nanowires will be at least 1 micrometer in length.

Nanopyramids may be 250 nm to 1 micrometer in height, such as 400 to 800 nm in height, such as about 500 nm.

Moreover, it will be preferred if the nanowires or nanopyramids grown have the same dimensions, e.g. to within 10% of each other. Thus, at least 90% (preferably substantially all) of the nanowires or nanopyramids on a substrate will preferably be of the same diameter and/or the same length (i.e. to within 10% of the diameter/length of each other). Essentially, therefore the skilled person is looking for homogeneity and nanowires or nanopyramids that are substantially the same in terms of dimensions.

The length of the nanowires or nanopyramids is often controlled by the length of time for which the growing process runs. A longer process typically leads to a (much) longer nanowire.

The nanowires or nanopyramids have typically a hexagonal cross sectional shape. The nanowire may have a cross sectional diameter of 25 nm to several micrometers (i.e. its thickness). As noted above, the diameter is ideally constant throughout the majority of the nanowire. Nanowire diameter can be controlled by the manipulation of the growth parameters such as the substrate temperature and/or the ratio of the atoms used to make the nanowire as described further below.

Moreover, the length and diameter of the nanowires or nanopyramids can be affected by the temperature at which they are formed. Higher temperatures encourage high aspect ratios (i.e. longer and/or thinner nanowires). The skilled person is able to manipulate the growing process to design nanowires or nanopyramids of desired dimensions.

The nanowires or nanopyramids of the invention are formed from at least one III-V compound, preferably group III-N compound. Group III options are B, Al, Ga, In, and TI. Preferred options here are Ga, Al and In.

Group V options are N, P, As, Sb. All are preferred. N is particularly preferred.

It is of course possible to use more than one element from group III and/or more than one element from group V. The compounds may be binary, ternary, quaternary, quinary etc. Preferred compounds for nanowire or nanopyramid manufacture include AIAs, GaSb, GaP, GaN, AlN, AlGaN, AIGalnN, GaAs, InP, InN, InGaN, InGaAs, InSb, InAs, or AIGaAs. Compounds based on Al, Ga and In in combination with N are one option. The use of GaN, AlGaN, AllnGaN or AlN is highly preferred. The above and below applies to both the nanowire/nanopyramid cores but also to any intrinsic or doped layers on top of/around the cores. Typically at least one of the intrinsic or doped layers on top of/around the cores is a ternary or quaternary compound layer, e.g. AlGaN.

Any additional layers on top of/around the nanowire/nanopyramid cores have individual thicknesses in the range of 10-1000 nm.

It is most preferred if the nanowires or nanopyramids consist of Ga, Al, In and N (along with any doping atoms as discussed below).

Ternary compounds may be of formula XYZ wherein X is a group III element, Y is a group III different from X, and Z is a group V element. The X to Y molar ratio in XYZ is preferably 0.1 to 0.9, i.e. the formula is preferably XₓY₁₋ₓZ where subscript x is 0.1 to 0.9.

Quaternary systems might also be used and may e.g. be represented by the formula AₓB₁₋ₓC_{y}D_{1-y} where A and B are group III elements and C and D are group V elements or AₓB_{y}C_{1-x-y}D where A, B and C are group III elements and D is a group V element. Again subscripts x and y are typically 0.1 to 0.9. Other options will be clear to the skilled man.

Whilst the use of ternary/quaternary nanowires or nanopyramids may be used, the use of binary materials such as GaN is preferred for the nanowire core.

The nanowire/nanopyramid may therefore comprises GaN, e.g. n-GaN or p-GaN, preferably p-GaN. This is particularly preferred for UVC/UVB devices. The nanowire or nanopyramid core may comprise, or consist of GaN, e.g. n-GaN or p-GaN, preferably p-GaN. GaN has been shown to grow well by SAG on a graphene hole mask in particular and forms a good interface with the graphene (outside the openings of graphene). Results are typically not as good when Al is present in the core because of a lower growth-selectivity. It is preferred, therefore, if the nanowire/nanopyramid core does not comprise Al. Nanoislands of Al-containing materials may be used to facilitate NW/NP nucleation, e.g. Al(Ga)N nanoislands.

Good conduction from the substrate, through a graphene mask, and through the nanowires is observed when GaN, e.g. n-GaN or p-GaN, is used for the nanowires/nanopyramids.

As previously discussed, the nanowires/nanopyramids of the invention typically extend over the surface of the mask layer. They grow/extend laterally (i.e. in the same plane as the substrate/mask), such that only the inner portion of the NW/NP core is formed over the opening in the mask layer mask. The NWs/NPs can grow out of the opening of the mask, and then grow sideways (i.e. radially) to cover at least a portion of the top surface of the mask layer.

### Doping

The nanowires or nanopyramids of the invention can contain a p-n, n-p, n-i-p, or p-i-n junction, e.g. to enable their use in LEDs. The nanowire or nanopyramid cores typically have the same doping type as the substrate (e.g. if the substrate is n-type doped, then the nanowire or nanopyramid core will be n-type, and vice versa). These can be in the form of additional layers on or around the NW/NP cores. NWs or nanopyramids of the invention are therefore optionally provided with an undoped intrinsic semiconductor region between a p-type semiconductor and an n-type semiconductor region. The intrinsic region may consist of single layer of material or a heterostructure consisting of multiple quantum wells and barriers.

It is therefore preferred if the nanowires or nanopyramids are doped. Preferably, the core is doped as well as at least one additional layer on top of/around the core. Doping typically involves the introduction of impurity ions into the nanowire, e.g. during MBE or MOVPE growth. The doping level can be controlled from ˜10¹⁵/cm³ to 10²⁰/cm³. The nanowires or nanopyramids can be p-type doped or n-type doped as desired. As mentioned above, the nanowire/nanopyramid core may for example be p-doped, e.g. p-GaN. This is particularly preferred for UVC/UVB devices.

The n(p)-type semiconductors have a larger electron (hole) concentration than hole (electron) concentration by doping an intrinsic semiconductor with donor (acceptor) impurities. Suitable donor (acceptors) for III-V compounds can be Te, Sn, Si (Be, Mg and Zn). Si can be amphoteric, either donor or acceptor depending on the site where Si goes to, depending on the orientation of the growing surface and the growth conditions. Dopants can be introduced during the growth process or by ion implantation of the nanowires or nanopyramids after their formation.

Higher carrier injection efficiency is required to obtain higher external quantum efficiency (EQE) of LEDs.

The nanowires/nanopyramids may comprise additional n, i-n, p-, i-p, n-i-p or p-i-n layers, preferably additional p-i-n or additional n-i-p layers, e.g. positioned on top of or around the NWs/NPs. The nanowires/nanopyramids may additionally comprise p-AlGaN, i-AlGaN, and n-AlGaN layers for example (e.g. in that order, with p-AlGaN being adjacent to the core, e.g. the p-GaN core). In a particular embodiment, therefore, the nanowires or nanopyramids comprise or consist of a p-GaN core, and additionally have p-AlGaN, i-AlGaN, and n-AlGaN layers thereon. At least one of these layers, e.g. the top n-AlGaN layer, can extend continuously over the plurality of the underlying layers and NW/NP cores.

The top layer (e.g. n-type layer, preferably n-AlGaN) can act as a top-emitting transparent electrode. By transparent is hereby meant transparent to the light emitted by the nanowires/nanopyramids, e.g. in the case of a UV-C LED, then the layer is transparent at least to UV-C light. In the case the photodetectors, by transparent is meant to transparent to any incoming light. E.g. if the composition/device is a solar cell, then transparent means transparent at least to solar light.

The nanowires/nanopyramids typically have an Al-containing layer. The increasing ionization energy of Mg acceptors with increasing Al content in AlGaN alloys makes it difficult to obtain higher hole concentration in AlGaN alloys with higher Al content. To obtain higher hole injection efficiency (especially in the cladding/barrier layers consisting of high Al content), the inventors have devised a number of strategies which can be used individually or together.

There are problems to overcome in the doping process therefore. It is preferred if the nanowires or nanopyramids of the invention comprise Al, e.g. in at least one of the layers. The use of Al is advantageous as high Al content leads to high band gaps, enabling UV-C LED emission from the active layer(s) of nanowires or nanopyramids and/or avoiding absorption of the emitted light in the doped cladding/barrier layers. Where the band gap is high, it is less likely that UV light is absorbed by this part of the nanowires or nanopyramids. The use therefore of AlN or AlGaN in nanowires or nanopyramids is preferred.

However, p-type doping of AlGaN or AlN to achieve high electrical conductivity (high hole concentration) is challenging as the ionization energy of Mg or Be acceptors increases with increasing Al content in AlGaN alloys. The present inventors propose various solutions to maximise electrical conductivity (i.e. maximise hole concentration) in AlGaN alloys with higher average Al content.

Where one of the layers/regions of the nanowires or nanopyramids comprise AlN or AlGaN, achieving high electrical conductivity by introducing p-type dopants is a challenge.

One solution relies on a short period superlattice (SPSL). In this method, we grow a superlattice structure consisting of alternating layers with different Al content instead of a homogeneous AlGaN layer with higher Al composition. For example, the cladding layer with 35% Al content could be replaced with a 1.8 to 2.0 nm thick SPSL consisting of, for example, alternating AlₓGa₁₋ₓN:Mg/Al_{y}Ga_{1-y}N:Mg with x=0.30/y=0.40. The low ionization energy of acceptors in layers with lower Al composition leads to improved hole injection efficiency without compromising on the barrier height in the cladding layer. This effect is additionally enhanced by the polarization fields at the interfaces. The SPSL can be followed with a highly p-doped GaN: Mg layer for better hole injection.

More generally, the inventors propose to introduce a p-type doped AlₓGa₁₋ₓN/Al_{y}Ga_{1-y}N short period superlattice (i.e. alternating thin layers of AlₓGa₁₋ₓN and Al_{y}Ga_{1-y}N) into (or onto) the nanowires or nanopyramid structure, where the Al mole fraction x is less than y, instead of a p-type doped Al_{z}Ga_{1-z}N alloy where x<z<y. It is appreciated that x could be as low as 0 (i.e. GaN) and y could be as high as 1 (i.e. AlN). The superlattice period should preferably be 5 nm or less, such as 2 nm, in which case the superlattice will act as a single Al_{z}Ga_{1-z}N alloy (with z being a layer thickness weighted average of x and y) but with a higher electrical conductivity than that of the Al_{z}Ga_{1-z}N alloy, due to the higher p-type doping efficiency for the lower Al content AlₓGa₁₋ₓN layers.

In the nanowires or nanopyramids comprising a p-type doped superlattice, it is preferred if the p-type dopant is an alkali earth metal such as Mg or Be.

A further option to solve the problem of doping an Al containing nanowire/nanopyramid follows similar principles. Instead of a superlattice containing thin AlGaN layers with low or no Al content, a nanostructure can be designed containing a gradient of Al content (mole fraction) in the growth direction of the AlGaN within the nanowires or nanopyramids. Thus, as the nanowires or nanopyramids grow, the Al content is reduced/increased and then increased/reduced again to create an Al content gradient within the nanowires or nanopyramids.

This may be called polarization doping. In one method, the layers are graded either from GaN to AlN or AlN to GaN. The graded region from GaN to AlN and AlN to GaN may lead to n-type and p-type conduction, respectively. This can happen due to the presence of dipoles with different magnitude compared to its neighbouring dipoles. The GaN to AlN and AlN to GaN graded regions can be additionally doped with n-type dopant and p-type dopant respectively.

In a preferred embodiment, p-type doping is used in AlGaN nanowires using Be as a dopant.

Thus, one option would be to start with a GaN nanowire/nanopyramid and increase Al and decrease Ga content gradually to form AlN, perhaps over a growth thickness of 100 nm. This graded region could act as a p-or n-type region, depending on the crystal plane, polarity and whether the Al content is decreasing or increasing in the graded region, respectively. Then the opposite process is effected to produce GaN once more to create an n-or p-type region (opposite to that previously prepared). These graded regions could be additionally doped with n-type dopants such as Si and p-type dopants such as Mg or Be to obtain n-or p-type regions with high charge carrier density, respectively. The crystal planes and polarity is governed by the type of nanowire/nanopyramid as is known in the art.

Viewed from another aspect therefore, the nanowires or nanopyramids of the invention comprise Al, Ga and N atoms wherein during the growth of the nanowires or nanopyramids the concentration of Al is varied to create an Al concentration gradient within the nanowires or nanopyramids.

In a third embodiment, the problem of doping in an Al containing nanowire or nanopyramid is addressed using a tunnel junction. A tunnel junction is a barrier, such as a thin layer, between two electrically conducting materials. In the context of the present invention, the barrier functions as an ohmic electrical contact in the middle of a semiconductor device.

In one method, a thin electron blocking layer is inserted immediately after the active region, which is followed by a p-type doped AlGaN cladding layer with Al content higher than the Al content used in the active layers. The p-type doped cladding layer is followed by a highly p-type doped cladding layer and a very thin tunnel junction layer followed by an n-type doped AlGaN layer. The tunnel junction layer is chosen such that the electrons tunnel from the valence band in p-AlGaN to the conduction band in the n-AlGaN, creating holes that are injected into the p-AlGaN layer.

In a particular embodiment, the nanowire or nanopyramid comprises two regions of doped GaN (one p-and one n-doped region) separated by an Al layer, such as a very thin Al layer. The Al layer might be a few nm thick such as 1 to 10 nm in thickness. It is appreciated that there are other optional materials that can serve as a tunnel junction which includes highly doped InGaN layers.

It is particularly surprising that doped GaN layers can be grown on the Al layer.

In one embodiment therefore, the invention provides a nanowire or nanopyramid having a p-type doped (Al)GaN region and an n-type doped (Al)GaN region separated by an Al layer.

The nanowires or nanopyramids of the invention can be grown to have a heterostructured form radially or axially. For example for an axial heterostructured nanowire or nanopyramid, p-n junction can be axially formed by growing a p-type doped core first, and then continue with an n-doped core (or vice versa). For a radially heterostructured nanowire or nanopyramid, p-n junction can be radially formed by growing the p-type doped nanowire or nanopyramid core first, and then the n-type doped semiconducting shell is grown (or vice versa)-a core shell nanowire. The core can also be axially heterostructured and the shell can be radially heterostructured. An intrinsic shell can be positioned between doped regions for a p-i-n nanowire. The NWs or nanopyramids are grown axially or radially and are therefore formed from a first section and a second section. The two sections are doped differently to generate a p-n junction or p-i-n junction. The first or second section of the NW or nanopyramid is the p-type doped or n-type doped section. The nanowires or nanopyramids can also have combined axial and radial heterostructures and have additional doped core or shell layers forming e.g. a p-p-i-n junction (see FIGS. 3 and 4).

It is particularly preferred, however, if the NW/NP cores have pyramidal tips, and any additional p/i/n layers mirror the topography (i.e. shape) of the underlying cores. The additional layers (which can be considered to form part of the nanowires/nanopyramids), can either be limited to the width of the NWs/NPs, or they may be in the form of a layer continuously covering at least a portion of the plurality of nanowires/nanopyramids. In a particular embodiment, at least one of the layers continuously covers at least a portion of the nanowires/nanopyramids (i.e. of the NW/NP cores, with potential intermediate layers between the NW/NP core and the top continuous layer). The layer(s) that continuously cover(s) at least a portion of the NWs/NPs may be continuous in its upper region, but may have voids in its lower region. The top layer (e.g. the top n-layer) may be continuous, e.g. it may cover at least 50% of the nanowires or nanopyramids, e.g. at least 75%, at least 90%, or at least 99% of the nanowires. This is beneficial since the doped top layer (e.g. n-layer) can act as a transparent current spreader with an acceptable sheet resistance without the continuous layer being too thick. Preferably, the top layer has a thickness of 100-2000 nm, e.g. 500 nm. Layers beneath the top layer (e.g. the i-layer and below) may be continuous or they may be non-continuous (i.e. limited to the width of the NWs/NPs).

### Epitaxy

The nanowires or nanopyramids of the invention preferably grow epitaxially on the substrate through the openings in the mask layer. They attach to the underlying substrate through covalent binding. Accordingly, at the junction of the substrate and the base of the nanowire, crystal planes are formed epitaxially with the nanowire. These build up, one upon another, in the same crystallographic direction thus allowing the epitaxial growth of the nanowire. Preferably the nanowires or nanopyramids grow vertically. The term vertically here is used to imply that the nanowires or nanopyramids grow perpendicular to the support. It will be appreciated that in experimental science the growth angle may not be exactly 90° but the term vertically implies that the nanowires or nanopyramids are within about 10° of vertical/perpendicular, e.g. within 5°. Because of the epitaxial growth via covalent bonding, it is expected that there will be an intimate contact between the nanowires or nanopyramids and the substrate.

As previously discussed, the nanowires/nanopyramids of the invention typically extend over the surface of the mask. The epitaxial relationship between the NW/NP core and the substrate is maintained, even though there is an intermediate mask layer. In a particular embodiment, therefore, the crystal structure of the NW/NP core matches that of the substrate (i.e. there is an epitaxial relationship between the two). In a particular embodiment, there is no epitaxial relationship between the NW/NP core and the mask layer. Nucleated NWs/NPs keep their crystal orientation (in epitaxy with the substrate) as they spread laterally over the mask layer. The interaction between the NWs/NPs and the mask layer is typically through van der Waals forces (very weak bonding).

The nanowires/nanopyramids therefore can grow such that the crystal orientation and facet orientations of said nanowires or nanopyramids are directed by the crystalline substrate. Thus, the crystal orientation and facet orientations are the same for all nanowires/nanopyramids.

Surprisingly, it has been found that the conduction from the substrate through the mask is better than through the openings in the mask. Graphene and other graphene-like materials (when suitably thin) act as a highly efficient tunnelling barrier. Thus the radial extension of the nanowire/nanopyramids over the top surface of the mask layer improves the electrical efficiency of the device.

It will be appreciated that the substrate comprises a plurality of nanowires or nanopyramids. Preferably the nanowires or nanopyramids grow about parallel to each other. It is preferred therefore if at least 90%, e.g. at least 95%, preferably substantially all nanowires or nanopyramids grow in the same direction from the same plane of the substrate.

It will be appreciated that there are many planes within a substrate from which epitaxial growth could occur. It is preferred if substantially all nanowires or nanopyramids grow from the same plane. It is preferred if that plane is parallel to the substrate surface. Ideally the grown nanowires or nanopyramids are substantially parallel. Preferably, the nanowires or nanopyramids grow substantially perpendicular to the substrate.

The nanowires of the invention should preferably grow in the [111] direction for nanowires or nanopyramids with cubic crystal structure and [0001] direction for nanowires or nanopyramids with hexagonal crystal structure. If the crystal structure of the growing nanowire or nanopyramid is cubic, then the (111) interface between the nanowire or nanopyramid and the substrate represents the plane from which axial growth takes place. If the nanowire or nanopyramid has a hexagonal crystal structure, then the (0001) interface between the nanowire or nanopyramid and the substrate represents the plane from which axial growth takes place. Planes (111) and (0001) both represent the same (hexagonal) plane of the nanowire, it is just that the nomenclature of the plane varies depending on the crystal structure of the growing nanowire.

The nanowires or nanopyramids are preferably grown by MBE or MOVPE. In the MBE method, the substrate is provided with a molecular beam of each reactant, e.g. a group III element and a group V element preferably supplied simultaneously. A higher degree of control of the nucleation and growth of the nanowires or nanopyramids on the substrate might be achieved with the MBE technique by using migration-enhanced epitaxy (MEE) or atomic-layer MBE (ALMBE) where e.g. the group III and V elements can be supplied alternatively.

A preferred technique is solid-source MBE, in which very pure elements such as gallium and arsenic are heated in separate effusion cells, until they begin to slowly evaporate (e.g. gallium) or sublimate (e.g. arsenic). The gaseous elements then condense on the substrate, where they may react with each other. In the example of gallium and arsenic, single-crystal GaAs is formed. The use of the term “beam” implies that evaporated atoms (e.g. gallium) or molecules (e.g. As₄ or As₂) do not interact with each other or vacuum chamber gases until they reach the substrate.

MBE takes place in ultra-high vacuum, with a background pressure of typically around 10⁻¹⁰ to 10⁻⁹ Torr. Nanostructures are typically grown slowly, such as at a speed of up to a few, such as about 10, μm per hour. This allows nanowires or nanopyramids to grow epitaxially and maximises structural performance.

In the MOVPE method, the substrate is/are kept in a reactor in which the substrate is provided with a carrier gas and a metal organic gas of each reactant, e.g. a metal organic precursor containing a group III element and a metal organic precursor containing a group V element preferably supplied simultaneously. The typical carrier gases are hydrogen, nitrogen or a mixture of the two. A higher degree of control of the nucleation and growth of the nanowires or nanopyramids on the substrate might be achieved with the MOVPE technique by using pulsed layer growth technique, where e.g. the group III and V elements can be supplied alternatively.

Having a nanowire or nanopyramid grown epitaxially provides homogeneity to the formed material which may enhance various end properties, e.g. structural, mechanical, optical or electrical properties.

Epitaxial nanowires or nanopyramids may be grown from gaseous, liquid or solid precursors. Because the substrate acts as a seed crystal, the deposited nanowire or nanopyramid can take on a lattice structure and orientation similar to that of the substrate. Epitaxy is different from other thin-film deposition methods which deposit polycrystalline or amorphous films, even on single-crystal substrates.

### Selective Area Growth of Nanowires or Nanopyramids

The nanowires or nanopyramids of the invention may be grown by selective area growth (SAG) method, e.g. in the case of III-nitride nanowire. Inside the growth chamber in case of MBE or inside the reactor in case of MOVPE, the substrate temperature can be set to a temperature suitable for the growth of the nanowire or nanopyramid in question. In case of MBE, the growth temperature may be in the range 300 to 1000° C. The temperature employed is, however, specific to the nature of the material in the nanowire. For GaN, a preferred temperature is 700 to 950 ° C., e.g. 800 to 900° C., such as 810° C. For AlGaN the range is slightly higher, for example 800 to 980° C., such as 830 to 950° C., e.g. 850° C.

It will be appreciated therefore that the nanowires or nanopyramids can comprise different group III-V semiconductors within the nanowire, e.g. starting with a GaN stem followed by an AlGaN component or AIGalnN component and so on.

Nanowire growth can be initiated by opening the shutter of the Ga effusion cell, the nitrogen plasma cell, and the dopant cell simultaneously initiating the growth of doped GaN nanowires or nanopyramids, hereby called as stem. The length of the GaN stem can be kept between 10 nm to several 100 s of nanometers. Subsequently, one could increase the substrate temperature if needed, and open the Al shutter to initiate the growth of AlGaN nanowires or nanopyramids. One could initiate the growth of AlGaN nanowires or nanopyramids on the substrate without the growth of GaN stem, but a GaN stem is preferred. n-and p-doped nanowires or nanopyramids can be obtained by opening the shutter of the n-dopant cell and p-dopant cell, respectively, during the nanowire or nanopyramid growth. For ex: Si dopant cell for n-doping of nanowires or nanopyramids, and Mg dopant cell for p-doping of nanowires or nanopyramids.

The temperature of the effusion cells can be used to control growth rate. Convenient growth rates, as measured during conventional planar (layer by layer) growth, are 0.05 to 2 μm per hour, e.g. 0.1 μm per hour. The ratio of Al/Ga can be varied by changing the temperature of the effusion cells.

The pressure of the molecular beams can also be adjusted depending on the nature of the nanowire or nanopyramid being grown. Suitable levels for beam equivalent pressures are between 1×10⁻⁷ and 1×10⁻⁴ Torr.

The beam flux ratio between reactants (e.g. group III atoms and group V molecules) can be varied, the preferred flux ratio being dependent on other growth parameters and on the nature of the nanowire or nanopyramid being grown. In the case of nitrides, nanowires or nanopyramids are always grown under nitrogen rich conditions.

It is an embodiment of the invention to employ a multistep, such as two step, growth procedure, e.g. to separately optimize the nanowire or nanopyramid nucleation and nanowire or nanopyramid growth.

In case of MOVPE, a significant benefit is that the nanowires or nanopyramids can be grown at a much faster growth rate. This method favours the growth of radial heterostructure nanowires or nanopyramids and microwires, for example: n-doped GaN core with shell consisting of intrinsic AlN/Al(In)GaN multiple quantum wells (MQW), AlGaN electron blocking layer (EBL), and p-doped (Al)GaN shell. This method also allows the growth of axial heterostructured nanowire or nanopyramid using techniques such as pulsed growth technique or continuous growth mode with modified growth parameters for e.g., lower V/III molar ratio and higher substrate temperature.

In more detail, the reactor must be evacuated after placing the sample, and is purged with N₂ to remove oxygen and water in the reactor. This is to avoid any damage to the mask layer (e.g. graphene) at the growth temperatures, and to avoid unwanted reactions of oxygen and water with the precursors. The total pressure is set to be between 50 and 400 Torr. After purging the reactor with N₂, the substrate is thermally cleaned under H₂ atmosphere at a substrate temperature of about 1200° C. The substrate temperature can then be set to a temperature suitable for the growth of the nanowire or nanopyramid in question. The growth temperature may be in the range 700 to 1200° C. The temperature employed is, however, specific to the nature of the material in the nanowire. For GaN, a preferred temperature is 800 to 1150° C., e.g. 900 to 1100° C., such as 1100° C. or 1000° C. For AlGaN the range is slightly higher, for example 900 to 1250° C., such as 1050 to 1250° C., e.g. 1250° C. or 1150° C.

The metal organic precursors for the nanowire or nanopyramid growth can be either trimethylgallium (TMGa), or triethylgallium (TEGa) for Ga, trimethylalumnium (TMAI) or triethylalumnium (TEAI) for Al, and trimethylindium (TMIn) or triethylindium (TEIn) for In. The precursors for dopants can be SiH₄ for silicon and bis(cyclopentadienyl)magnesium (Cp₂Mg) or bis(methylcyclopentadienyl)magnesium ((MeCp)₂Mg) for Mg. The flow rate of TMGa, TMAI and TMIn can be maintained between 5 and 100 sccm. The NH3 flow rate can be varied between 5 and 150 sccm.

In particular, the simple use of vapour-solid growth may enable nanowire or nanopyramid growth. Thus, in the context of MBE, simple application of the reactants, e.g. In and N, to the substrate without any catalyst can result in the formation of a nanowire. This forms a further aspect of the invention which therefore provides the direct growth of a semiconductor nanowire or nanopyramid formed from the elements described above on a substrate. The term direct implies therefore the absence of a film of catalyst to enable growth.

### Catalyst-Assisted Growth of Nanowires or Nanopyramids

The nanowires or nanopyramids of the invention may also be grown in the presence of a catalyst. A catalyst can be introduced into those openings to provide nucleating sites for nanowire or nanopyramid growth. The catalyst can be one of the elements making up the nanowire or nanopyramid so-called self-catalysed, or different from any of the elements making up the nanowire.

For catalyst-assisted growth the catalyst may be Au or Ag or the catalyst may be a metal from the group used in the nanowire or nanopyramid growth (e.g. group III metal), especially one of the metal elements making up the actual nanowire or nanopyramid (self-catalysis). It is thus possible to use another element from group III as a catalyst for growing a III-V nanowire or nanopyramid e.g. use Ga as a catalyst for a Ga-group V nanowire or nanopyramid and so on. Preferably the catalyst is Au or the growth is self-catalysed (i.e. Ga for a Ga-group V nanowire or nanopyramid and so on). The catalyst can be deposited onto the substrate in the holes patterned through the mask and optionally masking layer to act as a nucleation site for the growth of the nanowires or nanopyramids. Ideally, this can be achieved by providing a thin film of catalytic material formed over the masking layer after holes have been etched in the layers. When the catalyst film is melted as the temperature increases to the NW or nanopyramid growth temperature, the catalyst forms nanometre sized particle-like droplets on the substrate and these droplets form the points where nanowires or nanopyramids can grow.

This is called vapour-liquid-solid growth (VLS) as the catalyst is the liquid, the molecular beam is the vapour and the nanowire or nanopyramid provides the solid component. In some cases the catalyst particle can also be solid during the nanowire or nanopyramid growth, by a so called vapour-solid-solid growth (VSS) mechanism. As the nanowire or nanopyramid grows (by the VLS method), the liquid (e.g. gold) droplet stays on the top of the nanowire. It remains at the top of the nanowire or nanopyramid after growth and may therefore play a major role in contacting a top electrode.

As noted above, it is also possible to prepare self-catalysed nanowires or nanopyramids. By self-catalysed is meant that one of the components of the nanowire or nanopyramid acts as a catalyst for its growth.

For example, a Ga layer can be applied to the masking layer, melted to form droplets acting as nucleation sites for the growth of Ga containing nanowires or nanopyramids. Again, a Ga metal portion may end up positioned on the top of the nanowire.

In more detail and in the case of MBE-grown NWs, a Ga/In flux can be supplied to the substrate surface for a period of time to initiate the formation of Ga/In droplets on the surface upon heating of the substrate. The substrate temperature can then be set to a temperature suitable for the growth of the nanowire or nanopyramid in question. The growth temperature may be in the range 300 to 700° C. The temperature employed is, however, specific to the nature of the material in the nanowire, the catalyst material and the substrate material. For GaAs, a preferred temperature is 540 to 630° C., e.g. 590 to 630° C., such as 610° C. For InAs the range is lower, for example 420 to 540° C., such as 430 to 540° C., e.g. 450° C.

Nanowire growth can be initiated by opening the shutter of the Ga/In effusion cell and the counter ion effusion cell, simultaneously once a catalyst film has been deposited and melted.

The temperature of the effusion cells can be used to control growth rate. Convenient growth rates, as measured during conventional planar (layer by layer) growth, are 0.05 to 2 μm per hour, e.g. 0.1 μm per hour.

The pressure of the molecular beams can also be adjusted depending on the nature of the nanowire or nanopyramid being grown. Suitable levels for beam equivalent pressures are between 1×10⁻⁷ and 1×10⁻⁵ Torr.

The beam flux ratio between reactants (e.g. group III atoms and group V molecules) can be varied, the preferred flux ratio being dependent on other growth parameters and on the nature of the nanowire or nanopyramid being grown.

It has been found that the beam flux ratio between reactants can affect crystal structure of the nanowire. For example, using Au as a catalyst, growth of GaAs nanowires or nanopyramids with a growth temperature of 540° C., a Ga flux equivalent to a planar (layer by layer) growth rate of 0.6 μm per hour, and a beam equivalent pressure (BEP) of 9×10⁻⁶ Torr for As₄ produces wurtzite crystal structure. As opposed to this, growth of GaAs nanowires or nanopyramids at the same growth temperature, but with a Ga flux equivalent to a planar growth rate of 0.9 μm per hour and a BEP of 4×10⁻⁶ Torr for As₄, produces zinc blende crystal structure.

Nanowire diameter can in some cases be varied by changing the growth parameters. For example, when growing self-catalyzed GaAs nanowires or nanopyramids under conditions where the axial nanowire or nanopyramid growth rate is determined by the As₄ flux, the nanowire or nanopyramid diameter can be increased/decreased by increasing/decreasing the Ga:As₄ flux ratio. The skilled man is therefore able to manipulate the nanowire or nanopyramid in a number of ways. Moreover, the diameter could also be varied by growing a shell around the nanowire or nanopyramid core, making a core-shell geometry.

It is thus an embodiment of the invention to employ a multistep, such as two step, growth procedure, e.g. to separately optimize the nanowire or nanopyramid nucleation and nanowire or nanopyramid growth.

Moreover, the size of the holes can be controlled to ensure that only one nanowire or nanopyramid can grow in each hole. It is therefore preferred if only one nanowire or nanopyramid grows per hole in the mask. Finally, the holes can be made of a size where the droplet of catalyst that forms within the hole is sufficiently large to allow nanowire or nanopyramid growth. In this way, a regular array of nanowires or nanopyramids can be grown, even using Au catalysis.

### Coalescence

It may be that as numerous nanowires or nanopyramids grow from the substrate that the nanowires/nanopyramids coalesce at a certain distance from the substrate, or directly on top of the mask layer. It can be beneficial to form large area structures through coalescence of positioned nanowires/nanopyramids, or through coalescence of one of the top layers (e.g. n-AlGaN). The coalescence of nanowires may appear almost film like (e.g. like a corrugated film if the NWs/NPs have pyramidal tips, as discussed below). In a particular embodiment, however, the nanowire/nanopyramid cores are separate. In a particular embodiment, there is at least one layer (e.g. the top n-layer, e.g. n-AlGaN) which covers at least a portion of the plurality of nanowires/nanopyramids, e.g. by coalescence of said layer. In such a scenario the layer can be seen as a layer continuously covering the plurality of nanowires/nanopyramids, or at least a portion/majority thereof.

Coalescence refers to the side-on joining of two or more nanostructures during growth, typically through un-avoidable merging of ‘island’ nanostructures which have been grown in between them for the case of coalesced nanowires/nanopyramids. This results in a 2D or 3D structure. For coalescence, the nanostructures must preferably have their crystal lattices in the same orientation, such that the formation of gaps and dislocations can largely be eliminated, i.e. the coalescing nanowires/nanopyramids or doping layers thereof must preferably have nearly identical epitaxial relationship with respect to the substrate.

In a particular embodiment, the nanowire or nanopyramid cores are not coalesced. Preferably, any joining up of the nanowires/nanopyramids is caused at least by a top doped layer (e.g. n-AlGaN) which continuously covers at least a portion, preferably all of the plurality of nanowires/nanopyramids (or at least 50%, at least 75%, or at least 90%, or at least 99% of the nanowires/nanopyramids).

### Corrugated/Non-Planar Structure

It is preferred if the nanowires and/or nanopyramids have pyramidal tips. If there is a layer (e.g. n-AlGaN top layer) which continuously covers at least a portion of the NWs/NPs, then the top surface of the structure is preferably non-planar and/or corrugated, with pyramidal tips at the surface. The non-planar/corrugated layer/film is preferably therefore a non-planar layer/film comprising a plurality of protrusions, wherein the protrusions (e.g. pyramidal protrusions) are positioned on top of the nanopyramid/nanowire tips. The non-planar/corrugated structure is also on the nanometer scale, e.g. has a thickness of 10-1000 nm. The top layers mimic the topography of the underlying nanostructures. In a particular embodiment, the plurality of NWs/NPs (optionally coated in a layer which continuously covers at least a portion of them), has a corrugated structure, and/or is not planar. The structure is typically ridged, therefore. It is thus typically distinct from a planar thin film (i.e. flat film) which has been grown on a substrate.

The corrugated structure is beneficial as it can enable good light extraction for both transverse-electric (TE) and transverse-magnetic (TM) polarisation (see FIG. 5). Often, manufacturers of nanostructure devices etch corrugated/ridged designs to improve light extraction. In the present case, if pyramidal tipped NWs/NPs are used, the corrugation is obtained without having to perform any subsequent etching step. By using pyramidal tipped NW/NP shape, benefits in terms of ease of manufacture and light extraction are obtained, therefore.

The NW/NP cores at least may be separate (i.e. non-coalesced), but alternatively the entire NW/NP structures may be coalesced, such that the plurality of nanowires/nanopyramids resembles (or is) a corrugated film, i.e. ridged. The corrugated layer/film in this instance is preferably a non-planar layer comprising a plurality of protrusions, wherein the protrusions (e.g. pyramidal tips) are the tips of the nanopyramids/nanowires. Coalescence can be beneficial as the top continuous layer can act as a transparent electrode, and top finger electrodes can be positioned thereon.

The compositions of matter may therefore comprise a corrugated continuous III-V film present on top of the mask layer and extending from the openings of the mask layer. The film typically extends over the mask layer. As for the NWs/NPs, the film typically has an epitaxial relationship with the substrate. The non-planar continuous III-V structure is typically formed from a plurality of coalesced nanowires or nanopyramids grown in said openings, said nanowires or nanopyramids comprising at least one semiconducting group III-V compound. The film may have different layers corresponding to the different layers of the nanowires/nanopyramids described above.

The invention therefore provides a composition of matter, wherein said composition of matter comprises:
a doped substrate;
a mask layer on top of said substrate
wherein a plurality of openings are present through said mask layer; and
a corrugated continuous III-V film present on top of said layer and extending from said openings, e.g. formed from a plurality of coalesced nanowires or nanopyramids grown in said openings, said nanowires or nanopyramids comprising at least one semiconducting group III-V compound.

The NW/NP cores may be coalesced, and the additional intrinsic and/or doped layers (e.g. p-, i-, and/or n-layers) may continuously cover at least a portion of the coalesced nanowires/nanopyramids, preferably all. The corrugated film (typically grown by coalescence of a plurality of nanowires or nanopyramids) is typically grown from said substrate in said openings. The corrugated film could therefore be seen as a plurality of coalesced nanowires or nanopyramids grown from said substrate in said openings.

It will be appreciated that any discussion of nanowires/nanopyramids or additional intrinsic or doped layers for separate NWs/NPs also applied to structures in which the NWs/NPs or additional layers are coalesced. For example, the nanowire lengths discussed above would apply to coalesced nanowires lengths.

Any of the definitions for compositions comprising nanowires or nanopyramids (e.g. in relation to the nature of the materials including substrate, mask layer, NWs/NPs etc.) are applicable here, where technically viable. The materials for the nanowires/nanopyramids are applicable to the corrugated films. The corrugated films may comprise the same layers that the nanowires/nanopyramids comprise.

### Devices/Applications

Semiconductor nanowires or nanopyramids have wide ranging utility. They are semiconductors so can be expected to offer applications in any field where semiconductor technology is useful. They are primarily of use in integrated nanoelectronics and nano-optoelectronic applications.

An ideal device for their deployment might be a solar cell, transistor, laser LED or photodetector.

The semiconductor nanowires or nanopyramids have utility in LEDs, in particular UV LEDs and especially UV-A, UV-B, or UV-C LEDs, more preferably UV-C LEDs. The invention therefore provides a device, such as an opto-electronic device, comprising a composition as defined herein, e.g. a solar cell, photodetector or LED, preferably an LED, more preferably a UV LED, more preferably a UV-C LED. Preferably, the present devices (whether LED or other) emit or absorb light in the UV region, preferably UV-C region. In the present disclosure, any discussion about emission of light, in the context of light emitters such as UV LEDs, also applies to the absorption of light in the case of light absorbers.

In the compositions/devices of the invention, each individual NW/NP can be seen as an individual LED nanostructure (or individual photodetector/solar cell). The nanowires or nanopyramids comprise a light generating (or light absorbing) region.

It will be appreciated that devices of the invention are provided with electrodes to enable charge to be passed into the device. In order to create an optoelectronic device, the top of the nanowires or nanopyramids preferably comprise a top contact. In one embodiment, a conventional top contact is positioned on the top layer of the nanowires/nanopyramids, e.g. on the top n-type layer (e.g. n-AlGaN) positioned above the nanowire/nanopyramid cores (this top layer may extend continuously over the underlying layers and NW/NP cores). This top contact should have a finger design in order to reduce the amount of the contact that blocks light from exiting or entering the device. The top contact may be a strip-like sheet of metal with one dimension substantially larger than the other, e.g. ribbon-like. It is preferable, therefore, if the metal contact or metal stack contact layer does not cover the entirety of the nanowires/nanopyramids. The area covered by the n-contact is therefore typically 50% or less, preferably 20% or less of the top surface area of the nanowires or nanopyramids. A single finger contact can be used for one LED device and is made of metal that gives good ohmic contact to the top doped NW/NP layer. Alternatively, a plurality of finger contacts may be used. The opening of the finger (distance between neighbouring fingers) is typically larger than the NW/NP width so that most NWs/NPs do not have a metal finger on top of them (where light can escape out). The thick n-AlGaN top layer has low enough sheet resistance to spread the current laterally from the fingers before being injected in the active (intrinsic) area.

In one embodiment, a conventional top contact metal layer stack can be used. The contacts described herein are typically metallic, and e.g. chosen to have an ohmic behaviour with the top layer.

In a particular embodiment, it is preferred if light is emitted (or absorbed in the case of photodetectors) via the top of the device, i.e. in a direction substantially opposite to the substrate. It is preferred, therefore, if the device is not a flip chip device, or is not in a flip chip configuration. Preferably, there is no (continuous) reflective layer at the top of the NW/NP structure directing the light back towards the substrate. In a particular embodiment, the NWs/NPs do not comprise a (continuous) reflective layer covering the top of the NW/NP structure.

The contacts/contact pads can be electrically connected to the appropriate power supply lead of the device package.

As mentioned above, the doped substrate can act as an active injector of current. In a particular embodiment, there is a conductive pathway from the substrate, through the mask layer and into the nanowires or nanopyramids. In the case where the nanowires/nanopyramids extend laterally over the top surface of the mask, said conductive pathway is higher through the region of the nanowires/nanopyramids that extends over the mask layer. The conductive pathway is vertical, i.e. in the same axial direction as the nanowires/nanopyramids (see FIGS. 1-4). If the substrate is p-doped, the conductive pathway of the holes (which is the same as the direction of the current) is from bottom to top. For n-doped substrate the conductive pathway of the electrons is from bottom to top (NB: the direction of the current is defined as opposite to the direction of the electrons). Surprisingly, it has been found that the conduction from the substrate through the mask is higher than through the openings in the mask. Conduction through the openings in the mask layer can be poor due to the formation of insulating or defective layers at the NW/NP interface with the substrate, hence the importance of the NW/NP overgrowth laterally outside of the openings of the mask layer. In this context, smaller openings can be beneficial to maximise vertical conduction by tunnelling.

Unless otherwise stated, the term ‘bottom’ refers to the substrate side of the nanowires/nanopyramids, and the term ‘top’ refers to the side of the nanowires/nanopyramids that is opposite to the substrate.

The invention will now be further discussed in relation to the following non limiting examples and figures.

### BRIEF DESCRIPTION OF FIGURES

FIG. 1 shows positioned flat-tip nanowires grown epitaxially on a doped crystalline substrate carrying a mask layer through which holes have been etched. The nanowires first nucleate on the substrate epitaxially through the holes in the mask layer. As the nanowires continue to grow both axially and radially, they also grow on top of the mask layer maintaining the epitaxial relationship with the substrate. The nanowires are grown as an axial heterostructure in order to fabricate axial p-i-n nanowire device structures on a p-doped substrate (as shown in the figure) or n-i-p junction nanowire device structures on a n-doped substrate (not shown), respectively. The vertical dashed arrows in the p-i-n nanowire device indicate the hole current that is injected from the p-doped substrate into the p-doped nanowire by tunnelling through the mask layer.

FIG. 2 is analogous to FIG. 1, with the only difference being that the nanowires have a pyramidal tip. The nanowires are grown as an axial heterostructure in order to fabricate axial p-i-n nanowire device structures on a p-doped substrate (as shown in the figure) or n-i-p junction nanowire device structures on a n-doped substrate (not shown), respectively.

FIG. 3 is analogous to FIG. 2, with the only difference being that the nanowires are completely coalesced either directly in the doped nanowire core or as a result of the growth of an additional doped nanowire shell layer. The nanowires are grown as an axial heterostructure in order to fabricate axial p-i-n and p-p-i-n nanowire device structures on a p-doped substrate (as shown in the figure) or n-i-p and n-n-i-p junction nanowire device structures on a n-doped substrate (not shown), respectively.

FIG. 4 is analogous to FIG. 3, but with coalesced nanopyramids instead of coalesced nanowires. The nanopyramids are grown as an axial heterostructure in order to fabricate axial p-i-n and p-p-i-n nanopyramid device structures on a p-doped substrate (as shown in the figure) or n-i-p and n-n-i-p junction nanopyramid device structures on a n-doped substrate (not shown), respectively.

FIG. 5 shows a top-emitting nanowire GaN/AlGaN UV LED device grown on a hole etched mask layer carried on a p-doped Si substrate according to the invention. The dashed arrows show idealised TM and TE polarized light generated in the active multiple quantum well region from one exemplary nanowire and how they are directed towards the pyramidal top surface of some neighbouring nanowires. The LED device has a metal bottom contact to the Si substrate and a metal finger contact covering the top of some of the nanowires.

FIG. 6 (a) and (b) show top and 30° tilted-view scanning electron microscopy (SEM) images, respectively, of n-GaN nanowires grown on a graphene covered part of a doped Si wafer.

FIG. 6 (c) and (d) show top and 30° tilted-view scanning electron microscopy (SEM) images, respectively, of n-GaN nanowires grown on a doped Si wafer on a nearby area without any graphene.

FIG. 6e shows current density—voltage characteristics of the n-GaN nanowires that were grown on the graphene-covered part of the n⁺⁺-Si wafer (filled circles) and on the part of the n⁺⁺-Si wafer that was not covered with graphene (filled squares), respectively.

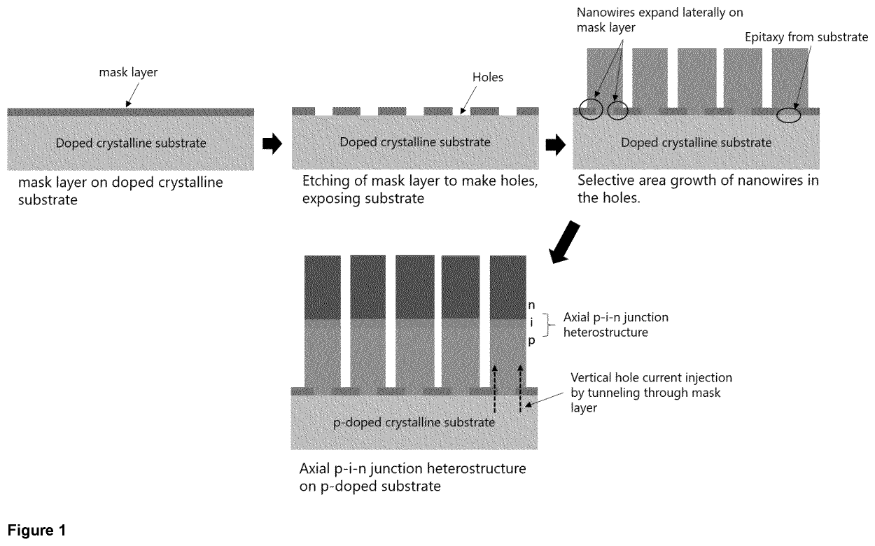

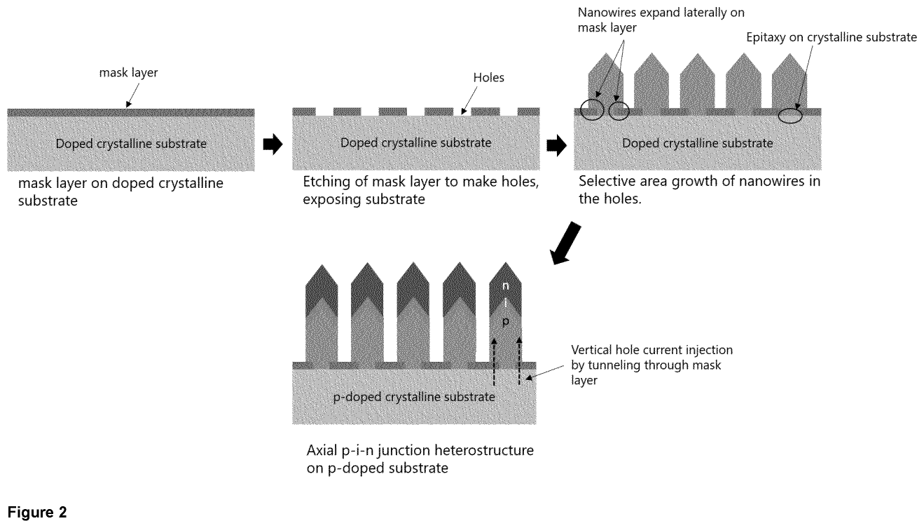

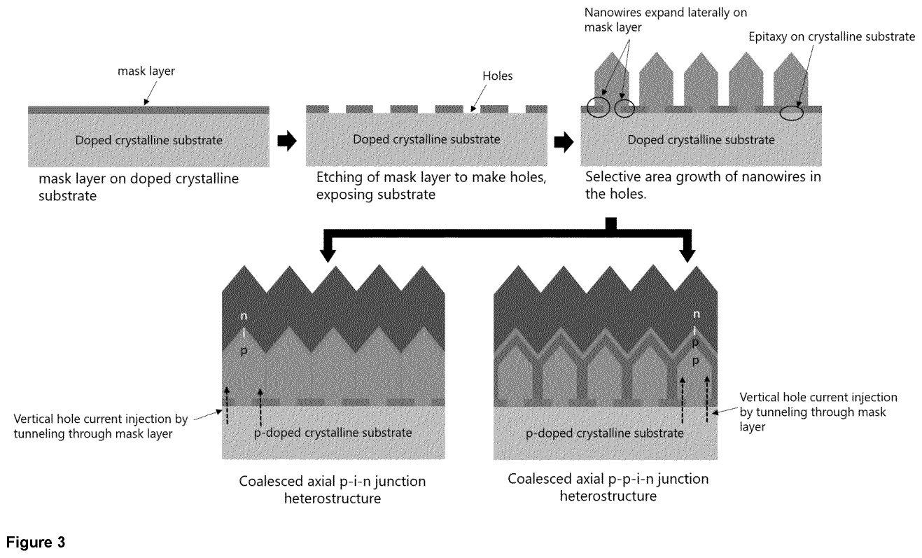

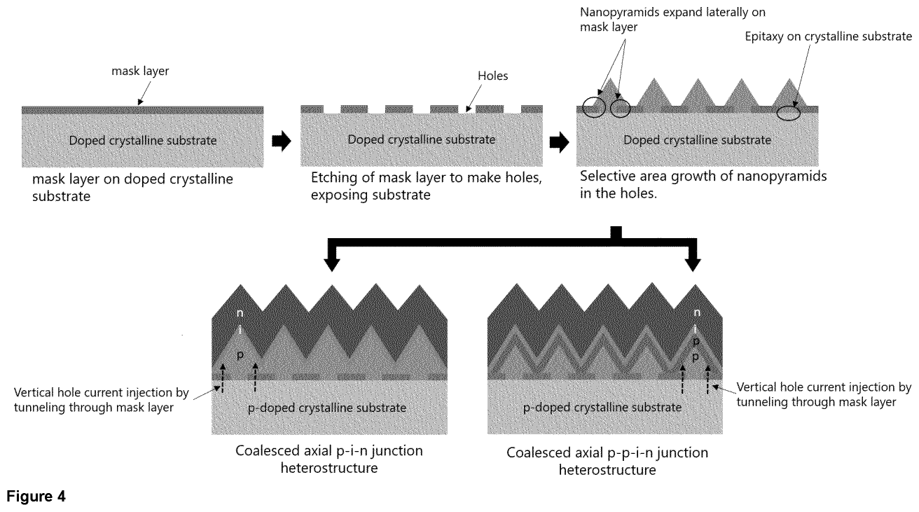

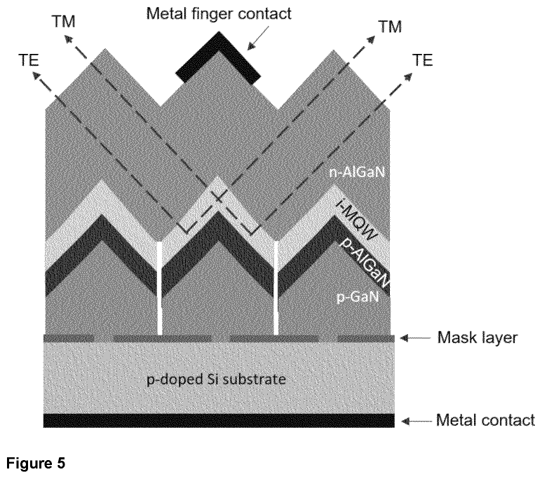

### EXAMPLES

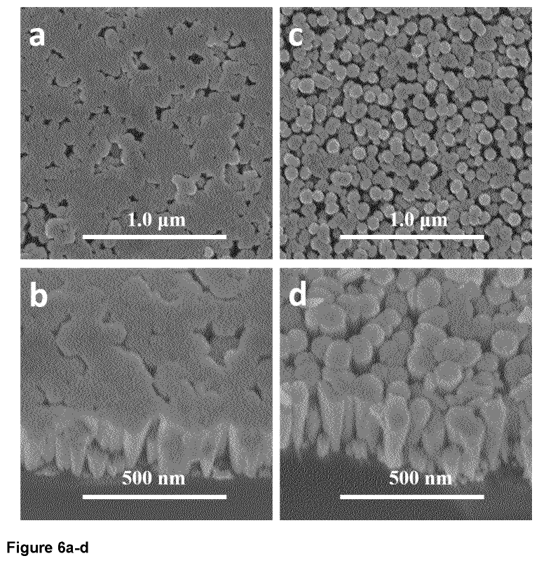

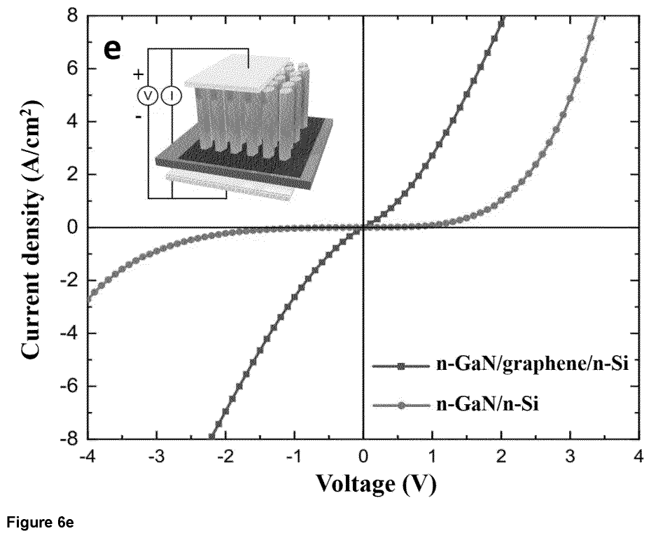

FIG. 6 shows experimental results of self-assembled n-GaN nanowires grown by plasma-assisted molecular beam epitaxy (MBE) on a 2 inch diameter n⁺⁺-Si wafer (resistivity<0.005 Ohm cm) doped to a level of ˜10¹⁹ /cm³ with the centre part covered with about 1 cm² of a single layer of polycrystalline CVD graphene (i.e. one atomic layer of carbon atoms in a hexagonal pattern). HF-etching was done immediately before the graphene transfer to reduce the thickness of the native SiO₂ present on the Si substrate. After the graphene transfer the sample was loaded into the MBE chamber. Growth of the silicon-doped n-GaN nanowires was then carried out under nitrogen rich conditions in the MBE system equipped with a Knudsen Si cell, a SUMO Ga cell, and a Riber S63 RF nitrogen plasma source. A two-step procedure was used for the n-GaN nanowire growth where the first step was done with a Ga flux of 0.6×10⁻⁷ Torr at a growth temperature of 720° C. for 30 min followed by a ramp up of 11 min before a second growth step with a Ga flux of 1.8×10⁻⁷ Torr at a growth temperature of 750° C. for 60 min was performed. The Si cell was kept at 1200° C. in the first growth step and at 1255° C. in the second growth step whereas the N plasma was always kept at a nitrogen flow of 0.8 sccm at an RF power of 450 W.

FIG. 6 (a) and (b) show top and 30° tilted-view scanning electron microscopy (SEM) images, respectively, of the n-GaN nanowires grown on the graphene covered part of the Si wafer. From the top-view image in (a) it can be seen that the GaN nanowire facets are aligned with each other in the same orientation and are epitaxially coalesced in large areas showing that the GaN nanowires are epitaxial with the Si(111) substrate and that the nucleation of the GaN nanowires therefore are initiated through openings in the graphene.

In order to measure the conduction between the n⁺⁺-Si wafer and the n-GaN nanowires, 1 mm² devices were fabricated with ohmic metal contacts on the bottom (negative potential) of the n⁺⁺-Si wafer and on the top (positive potential) of the n-GaN nanowires, as schematically indicated in the inset of FIG. 6 (e). The resulting current density-voltage characteristics of the n-GaN nanowires that were grown on the graphene-covered part of the n⁺⁺-Si wafer (filled circles) and on the part of the n⁺⁺-Si wafer that was not covered with graphene (filled squares), respectively, is shown in FIG. 6 (e). It can be seen that the electrical conduction in both the positive as well as in the negative biased direction is much higher on the device that is made on the graphene-covered part of the Si wafer with close to ohmic behaviour, whereas on the part without the graphene, an onset voltage of about 1 and −2 V is seen in the forward and backward direction, respectively. The high conduction and near ohmic behaviour when measured on the graphene-covered part of the Si substrate indicates that tunnelling takes place.

1. A composition of matter comprising
a doped substrate;
a mask layer having a thickness of 2 nm or less on top of said substrate, wherein a plurality of openings are present through said mask layer; and
wherein
a plurality of nanowires or nanopyramids are grown from said substrate in said openings, said nanowires or nanopyramids comprising at least one semiconducting group III-V compound.

2. A composition as claimed in any preceding claim wherein said substrate is p-doped or n-doped, preferably p-doped.

3. A composition as claimed in any preceding claim, wherein said substrate is doped to a level of 10¹⁵/cm³ to 10²²/cm³, e.g. 10¹⁸/cm³ to 10²¹/cm³.

4. A composition as claimed in any preceding claim, wherein said substrate is a silicon, Ge, SiC, Ga₂O₃ or group III-V substrate, preferably a silicon substrate.

5. A composition as claimed in any preceding claim, wherein the doped substrate acts as a current injector.

6. A composition as claimed in any preceding claim, wherein the composition comprises an electrical contact on the doped substrate.

7. A composition as claimed in any preceding claim, wherein said mask layer is a two-dimensional material such as graphene, hexagonal-BN, MoS₂, WS₂, MoSe₂, NbSe₂, TaSe₂, Bi₂Te₃, Bi₂Se₃ or NiTe₂ mask layer, preferably a graphene mask layer, preferably an atomically thick graphene mask layer.

8. A composition as claimed in any preceding claim, wherein said nanowires or nanopyramids comprise GaN, preferably comprise a GaN core, preferably a doped GaN core, preferably a p-GaN core.

9. A composition as claimed in any preceding claim, wherein the nanowires or nanopyramids extend laterally (i.e. radially) over the mask layer outside of the openings.

10. A composition as claimed in any preceding claim, wherein the mask layer acts as a tunnelling barrier, e.g. for current conduction from the substrate into the nanowires/nanopyramids, or from the nanowires/nanopyramids into the substrate, e.g. as a tunnelling barrier for vertical hole or electron tunnel injection from the doped substrate to the nanowires or nanopyramids.

11. A composition as claimed in any preceding claim in which said mask layer has a thickness of 1.5 nm or less, more preferably a thickness of 1 nm or less, more preferably a thickness of 0.9 nm or less, more preferably 0.8 nm or less, more preferably 0.7 nm or less, more preferably 0.6 nm or less, more preferably 0.5 nm or less.

12. A composition as claimed in any preceding claim, wherein the mask layer is a two-dimensional material and the mask layer is 1-5 atomic sheets thick, preferably 1-4 atomic sheets thick, preferably 1-3 atomic sheets thick, preferably 1-2 atomic sheets thick, preferably 1 atomic sheet thick.

13. A composition as claimed in any preceding claim, wherein said substrate is a silicon substrate and comprises a layer of native silicon dioxide at the interface with the mask layer, preferably wherein said layer of silicon dioxide has a thickness of less than 10 nm, preferably less than 5 nm, preferably less than 3 nm, preferably less than 2 nm, e.g. 1-5 nm, 1-2 nm or 2-3 nm.

14. A composition as claimed in any preceding claim, wherein the nanowires or nanopyramids comprise a p-n or p-i-n junction, preferably wherein said p-n or p-i-n junction comprises p-AlGaN and n-AlGaN, preferably wherein the nanowires or nanopyramids comprise a p-i-n junction comprising p-AlGaN, i-AlGaN, and n-AlGaN.

15. A composition as claimed in claim 14, wherein the intrinsic layer (i-layer) is a multiple quantum well.

16. A composition as claimed in any preceding claim, wherein
if the nanowire/nanopyramid cores are p-doped, then additional intrinsic and n-type layers are present on the nanowire/nanopyramid cores, preferably additional p-type, intrinsic and n-type layers are present on the nanowire/nanopyramid cores; or
if the nanowire/nanopyramid cores are n-doped, then additional intrinsic and p-type layers are present on the nanowire/nanopyramid cores, preferably additional n-type, intrinsic and p-type layers are present on the nanowire/nanopyramid cores.

17. A composition as claimed in any preceding claim, wherein the composition of matter is an electronic or optoelectronic device, preferably a transistor, solar cell, laser, photodetector or LED, preferably a LED, preferably a UV LED, preferably a UVC LED.

18. A composition as claimed in any preceding claim, wherein the composition is not in flip chip configuration, or wherein the composition does not comprise a light reflective layer covering (e.g. continuously covering) the top of the nanowires or nanopyramids.

19. A composition as claimed in any preceding claim, wherein the top layer, preferably top n-layer, of the p-n or p-i-n junction acts as a transparent current spreader.

20. A composition as claimed in any preceding claim, wherein the tips of the nanowire/nanopyramid cores are pyramidal.

21. A composition as claimed in any preceding claim, comprising a layer continuously covering at least a portion of the plurality of nanowires/nanopyramids, e.g. at least 50%, at least 75%, at least 90%, or at least 99% of the nanowires/nanopyramids.

22. A composition as claimed in claim 21, wherein the top layer of the nanowires/nanopyramids has a non-planar, e.g. corrugated structure.

23. A composition as claimed in claims 21-22, wherein said continuous layer is a top doped layer, preferably an n-type top doped layer, e.g. n-AlGaN.

24. A composition as claimed in any preceding claim in which said nanowires or nanopyramids are doped.

25. A composition as claimed in any preceding claim in which said nanowires or nanopyramids are core-shell or radially heterostructured, preferably axially heterostructured.

26. A composition as claimed in any preceding claim wherein a metal contact or metal stack contact layer is present on top of said nanowires or nanopyramids, preferably wherein said metal contact or metal stack contact layer has a finger design, e.g. is a strip.

27. A composition as claimed in any preceding claim in which said nanowires or nanopyramids grow epitaxially from the substrate through the openings in mask, i.e. wherein said nanowires or nanopyramids are epitaxial with the substrate.

28. A composition as claimed in any preceding claim, wherein an electrical contact is in contact with the mask layer.

29. A composition as claimed in any preceding claim, wherein the openings in the mask layer are defects or patterned holes.

30. A composition of matter comprising:
a doped substrate;
a mask layer having a thickness of 2 nm or less on top of said substrate
wherein a plurality of openings are present through said mask layer; and
a corrugated continuous III-V film present on top of said mask layer and extending from said openings, e.g. formed from a plurality of coalesced nanowires or nanopyramids grown in said openings, said nanowires or nanopyramids comprising at least one semiconducting group III-V compound.

31. A device, such as an opto-electronic device, comprising a composition as claimed in any of claims 1-30, e.g. a solar cell, photodetector, transistor, laser, or LED, preferably an LED, more preferably a UV LED, more preferably a UV-C LED.

32. A process for preparing a composition as claimed in any of claims 1-29 comprising:

(I) providing a mask layer having a thickness of 2 nm or less carried on a doped substrate;
(II) growing a plurality of nanowires or nanopyramids from said substrate in a plurality of openings in said mask layer, said nanowires or nanopyramids comprising at least one semiconducting group III-V compound.

33. A process for preparing a composition as claimed in claim 30 comprising:

(I) providing a mask layer having a thickness of 2 nm or less carried on a doped substrate;
(II) growing a plurality of nanowires or nanopyramids from said substrate in a plurality of openings in said mask layer, said nanowires or nanopyramids comprising at least one semiconducting group III-V compound, to the point that the nanowires or nanopyramids are coalesced.

34. A process as claimed in claim 32-33, further comprising a step of (III) growing additional layers such that a p-n or p-i-n junction is provided in the nanowires or nanopyramids.

35. A process as claimed in claim 32 comprising:

(I) providing a mask layer having a thickness of 2 nm or less carried on a doped substrate;
(I′) etching a plurality of holes through said mask layer; and
(II) growing a plurality of nanowires or nanopyramids from said substrate in said holes, said nanowires or nanopyramids comprising at least one semiconducting group III-V compound.

36. A process for preparing a composition as claimed in claim 33 comprising:
(I) providing a mask layer having a thickness of 2 nm or less carried on a doped substrate;
(I′) etching a plurality of holes through said mask layer; and
(II) growing a plurality of nanowires or nanopyramids from said substrate in said holes, said nanowires or nanopyramids comprising at least one semiconducting group III-V compound, to the point that the nanowires or nanopyramids are coalesced.

37. A composition of matter comprising
a metal substrate;
a mask layer having a thickness of 2 nm or less on top of said substrate,
wherein a plurality of openings are present through said mask layer; and wherein
a plurality of nanowires or nanopyramids are on said substrate in said openings, said nanowires or nanopyramids comprising at least one semiconducting group III-V compound.

38. A composition of matter comprising:
a metal substrate;
a mask layer having a thickness of 2 nm or less on top of said substrate
wherein a plurality of openings are present through said mask layer; and
a corrugated continuous III-V film present on top of said mask layer and extending from said openings, e.g. formed from a plurality of coalesced nanowires or nanopyramids grown in said openings, said nanowires or nanopyramids comprising at least one semiconducting group III-V compound.

39. A process for the preparation of a device, such as an opto-electronic device, comprising steps of:
(I) removing the nanowires or nanopyramids from the substrate in the composition of any of claims 1-29; and
(II) transferring the removed nanowires or nanopyramids to a different substrate, wherein said second substrate is doped or undoped.

40. The process as claimed in claim 39, wherein the mask layer is removed in combination with the nanowires or nanopyramids from the substrate, or wherein the nanowires or nanopyramids are removed from both the substrate and the mask layer.

41. The process as claimed in claim 39 or 40, wherein the different substrate is
a metal substrate (e.g. Cu, Ti, Mo, stainless steel), preferably wherein said different substrate provides an electrical contact (e.g. bottom contact); or
an insulating substrate.

42. A process for the preparation of a device, such as an opto-electronic device, comprising steps of:
(I) removing the continuous III-V film from the substrate in the composition of claim 30; and
(II) transferring the removed III-V film to a different substrate, wherein said second substrate is doped/conductive or undoped/insulating.
